(19) United States
(12) Patent Application Publication
(10) Pub. No.: US 2026/0265427 A1
(43) Pub. Date: Sep. 10, 2026

(54) COMPOSITION AND CURED PRODUCT THEREOF

(71) Applicant: Denka Company Limited, Tokyo (JP)

(72) Inventors: Suguru ONUKI, Chuo Tokyo (JP); Ryosuke KANTO, Chuo Tokyo (JP); Yuhei ISHIGAKI, Chuo Tokyo (JP); Yuta MAEDA, Chuo Tokyo (JP); Jun YOSHIDA, Chuo Tokyo (JP); Toru ARAI, Chuo Tokyo (JP)

(21) Appl. No.: 19/162,961

(22) PCT Filed: Mar. 14, 2024
(86) PCT No.: PCT/JP2024/010017

§ 371 Date: Sep. 8, 2025

(30) Foreign Application Priority Data
Mar. 15, 2023 (JP) 2023-041092
May 30, 2023 (JP) 2023-089033

(51) Int. Cl. C08F 36/02; C08K 3/02; C08K 3/08

(52) U.S. Cl. CPC C08F 36/02; C08K 3/02; C08K 3/08; C08K 2003/0812

(57) ABSTRACT

A composition includes (A) an olefin-aromatic vinyl compound-aromatic polyene copolymer, (B) boron at a content of 0.2 ppm or more as measured by ICP-emission spectroscopy in accordance with JIS K0116: 2014, and (C) aluminum at a content in the range of 100 ppm or more and 2000 ppm or less as measured by ICP-emission spectroscopy in accordance with JIS K0116: 2014, the composition having a number-average molecular weight of 40000 or smaller.

### TECHNICAL FIELD

The present invention relates, for example, a curable composition and a cured product thereof.

### BACKGROUND ART

As communication frequencies shift to gigahertz and higher zones of frequences, there are growing needs for multilayer substrates, transmission lines, antennas, and the like made of CCL or FCCL containing an insulation material having low dielectric characteristics. For use in such multilayer substrates and the like, the insulation material is required to have impregnating properties and therefore needs to have lower viscosity.

Patent Literature 1 discloses a cured product consisting of an ethylene-olefin (aromatic vinyl compound)-aromatic polyene copolymer and a nonpolar vinyl compound copolymer, the ethylene-olefin (aromatic vinyl compound)-aromatic polyene copolymer being obtained from a specific coordination polymerization catalyst and having specific composition and formulation. This technique can easily produce a cross-linkable hydrocarbon-based copolymer macromonomer having a functional group of an aromatic vinyl group because only one of two vinyl groups of the aromatic polyene (divinylbenzene) is selectively copolymerized and the remaining vinyl group is preserved.

Reduction in molecular weight has been required for achieving low viscosity for multilayer substrate application of CCL or the like. As disclosed in Patent Literature 2, it is known that a low-molecular-weight copolymer can be obtained by using a single-site coordination polymerization catalyst having a small ligand and relatively low polymerization activity.

A method for producing an ethylene-olefin (aromatic vinyl compound)-aromatic polyene copolymer using a coordination polymerization catalyst and a boron co-catalyst is also known (Patent Literature 3).

### CITATION LIST

### Patent Literature

Patent Literature 1: Japanese Patent Laid-Open No. 2009-161743
Patent Literature 2: International Publication No. WO 2022/014599
Patent Literature 3: International Publication No. WO 2017/122295

### SUMMARY OF INVENTION

### Technical Problem

However, since signal frequencies used are presumed to be higher frequences in the future, insulation materials are desired to have a lower dielectric tangent (dielectric loss). Particularly, in response to higher frequencies of package substrates and finer wiring inside the substrates, there are growing expectations for insulation materials having more homogeneous composition at a micro level while having a low dielectric tangent. In general, these insulation materials are supplied in a varnish state containing a solvent and concentrated (the solvent is removed), for use, in the step of producing a substrate. It is presumably important to be transparent in a highly concentrated state during solvent removal, in other words, to have homogeneous composition to the extent that light scattering does not occur. The present inventors have focused on the content of impurities in such a copolymer and completed the invention by finding that the amount of impurities is kept in a given range, whereby a solution having a high concentration of the copolymer retains homogeneity (transparency), and the dielectric tangent of the resulting cured product is more reduced.

### Solution to Problem

The present inventor has conducted diligent studies to solve the problems and consequently completed the present invention by conceiving the idea that problems mentioned above can be solved by controlling the content of a specific element in a composition. Specifically, the present invention provides the following various specific aspects.

### Aspect 1

A composition comprising
(A) an olefin-aromatic vinyl compound-aromatic polyene copolymer,
(B) boron at a content of 0.2 ppm or more as measured by ICP-emission spectroscopy in accordance with JIS K0116:2014, and
(C) aluminum at a content in the range of 100 ppm or more and 2000 ppm or less as measured by ICP-emission spectroscopy in accordance with JIS K0116:2014, the composition having a number-average molecular weight of 40000 or smaller.

### Aspect 2

The composition according to item 1, wherein the component (A) satisfies the following conditions (1) to (4):
(1) a number-average molecular weight of the copolymer is 5000 or larger and 40000 or smaller,
(2) an aromatic vinyl compound monomer unit is an aromatic vinyl compound having 8 or more and 20 or less carbon atoms, and a content of the aromatic vinyl compound monomer unit is 0% by mass or more and 70% by mass or less,
(3) an aromatic polyene monomer unit is one or more selected from polyenes having 5 or more and 20 or less carbon atoms and having a plurality of vinyl groups and/or vinylene groups in a molecule, and
(4) an olefin monomer unit is one or more selected from olefins having 2 or more and 20 or less carbon atoms, and a total amount of the olefin monomer unit, the aromatic vinyl compound monomer unit, and the aromatic polyene monomer unit is 100% by mass.

### Aspect 3

The composition according to item 2, wherein the condition (3) satisfies the following condition (3a):
(3a) the aromatic polyene monomer unit is one or more selected from polyenes having 5 or more and 20 or less carbon atoms and having a plurality of vinyl groups and/or vinylene groups in a molecule, and a content of the vinyl groups and/or the vinylene groups derived from the aromatic polyene monomer unit is 1.5 or more and 20 or less per number-average molecular weight.

### Aspect 4

The composition according to item 1, wherein the content of the component (B) as measured by ICP-emission spectroscopy in accordance with JIS K0116:2014 is in the range of 0.2 ppm or more and 10 ppm or less.

### Aspect 5

The composition according to item 1 or 2, wherein the content of the component (C) is in the range of 100 ppm or more and 1500 ppm or less.

### Aspect 6

The composition according to item 5, wherein the content of the component (C) is in the range of 100 ppm or more and 1100 ppm or less.

### Aspect 7

The composition according to any of items 1 to 6, wherein a value of a ratio Mw/Mn of a weight-average molecular weight (Mw) to the number-average molecular weight (Mn) is 10 or less.

### Aspect 8

A cured product of the composition according to any one of items 1 to 7.

### Aspect 9

A CCL substrate, an FCCL substrate, an interlayer insulation material, or a coverlay comprising the cured product according to item 8.

### Advantageous Effect of Invention

The present invention produces, for example, an effect of eliminating the need of removing aluminum from a system and being able to impair neither a dielectric tangent nor the transparency of a solution.

### DESCRIPTION OF EMBODIMENTS

Hereinafter, the mode for carrying out the present invention will be described in detail. However, embodiments given below are illustrations for describing the present invention, and the present invention is not limited thereby. Specifically, the present invention can be carried out through arbitrary changes or modifications made without departing from the spirit of the present invention. In the present specification, the notation of a numerical range of, for example, “1 to 100”, encompasses both the lower limit value “1” and the upper limit value “100”. The same holds true for the notation of other numerical ranges.

In the present specification, a sheet conceptually encompasses a film. In the present specification, the term “film” conceptually encompasses even a sheet. In the present specification, a composition conceptually encompasses a varnish.

Specifically, a composition, particularly, in a liquid state is described as a varnish. In the present specification, an interlayer insulation material conceptually includes an interlayer adhesive. In the present specification, a numerical range includes its lower limit value and upper limit value unless otherwise specified.

A composition provided by an embodiment of the present invention comprises (A) an olefin-aromatic vinyl compound-aromatic polyene copolymer, (B) boron at a content of 0.2 ppm or more as measured by ICP-emission spectroscopy in accordance with JIS K0116:2014, and (C) aluminum at a content in the range of 100 ppm or more and 2000 ppm or less as measured by ICP-emission spectroscopy in accordance with JIS K0116:2014, the composition having a number-average molecular weight in a predetermined range. The component (A) corresponds to a major component of the present composition. The component (A) is mixed with predetermined amounts of the component (B) and the component (C) and thereby suppresses a loss of the transparency of a solution through a synergistic effect thereof and furthermore, can decrease a dielectric tangent. The present composition is classified into an LDM (low dielectric material) resin in the art.

The component (B) can be derived from an arbitrary molecule containing a boron atom and can be preferably derived from a catalyst and/or a co-catalyst, more preferably derived from a co-catalyst.

The content of the component (B) in the present composition is 0.2 ppm or more and can be preferably 0.2 ppm or more and 10 ppm or less, further preferably 0.2 ppm or more and 5.0 ppm or less. Throughout the present specification, the amounts of the component (B) and the component (C) mentioned later are measured by ICP-emission spectroscopy in accordance with JIS K0116:2014.

Examples of a compound capable of containing the component (B) include organic boron compounds and inorganic boron compounds. Examples of the organic boron compound include, but are not particularly limited to, tris(perfluorophenyl) borane (FAB), tritium tetra(perfluorophenyl) borate (TRI-FABA, also called triphenylmethylium tetrakis(pentafluorophenyl) borate or tritium tetrakis(pentafluorophenyl) borate), N,N-dimethylanilinium tetrakis(pentafluorophenyl) borate (DAN-FABA), tris(pentafluorophenyl) borane (TPB), tris(pentafluorophenyl) borane trihydrate (TPB-3W), and triethyl borate. Examples of the inorganic boron compound include, but are not particularly limited to, boric acid, sodium borate, nickel boron, manganese (II) borate, ammonium pentaborate, and potassium fluoroborate. Preferably, an organic boron compound can be used.

Preferably, a co-catalyst containing a fluorine atom can be used as a co-catalyst containing the component (B). Without wishing to be bound by any specific theory, a co-catalyst containing both of a boron atom and a fluorine atom may trap an aluminum atom serving as the component (C) to form the structure of an aluminum-boron cluster compound, and is expected to easily suppress an adverse effect of a predetermined amount of the component (C) mentioned later. Albeit hypothetical, when such a cluster compound is formed, it is predicted that molecules are easily dispersed in an organic solvent so that the transparency of a solution is easily improved. If the amount of the component (C) falls outside this predetermined range, it is considered that this effect cannot be obtained.

The component (C) can be derived from an arbitrary molecule containing an aluminum atom and can be preferably derived from a catalyst, a co-catalyst, and/or a scavenger. In the present specification, the scavenger refers to a compound that is added to a system in order to remove impurities (water, etc.) capable of having an adverse effect on polymerization reaction.

The content of the component (C) in the present composition needs to be 100 ppm or more and 2000 ppm or less. If the amount of the component (C) falls outside this range, a problem tends to easily arise, such as insufficient polymerization reaction in a system, deteriorated dielectric characteristics, or deteriorated transparency. Preferably, the content of the component (C) can be in the range of 100 ppm or more and 1500 ppm or less, more preferably 100 ppm or more and 1300 ppm or less, further preferably 100 ppm or more and 1100 ppm or less.

Examples of a compound capable of containing the component (C) include organic aluminum compounds. Examples of the organic aluminum compound include, but are not particularly limited to, alkylaluminum compounds that may be used as scavengers or co-catalysts, such as triisobutylaluminum (TIBAL) and triethylaluminum (TEA). Examples thereof also include, but are not particularly limited to, aluminum compounds that may be used as co-catalysts, such as methylaluminoxane (also called methylalumoxane or MAO), modified methylaluminoxane (also called modified MAO or MMAO), and solid polymethylaluminoxane (also called SMAO). Such a co-catalyst is commercially available under trade names of TMAO-312, TMAO-211, TMAO-212, MMAO-3A, TMAO-341, and Solid MAO from Tosoh Finechem Corp. In a preferable embodiment, an alkylaluminum compound is used as the compound capable of containing the component (C), and use of aluminoxanes can be avoided.

The present composition may further comprise an additional metal element in addition to the component (B) and the component (C) and may preferably comprise a transition metal element, more preferably zirconium and/or hafnium, further preferably zirconium. A compound that brings about such a metal element can be a compound that may be used as a catalyst or a co-catalyst. Examples of such a compound include, but are not particularly limited to, dimethylmethylene biscyclopentadienyl zirconium dichloride, diphenylmethylene biscyclopentadienyl zirconium dichloride, dimethylmethylene (cyclopentadienyl) (1-indenyl) zirconium dichloride, and diphenylmethylene (cyclopentadienyl) (1-indenyl) zirconium dichloride.

Other examples of the compound that brings about the metal element also include transition metal compounds represented by the following general formula (I):

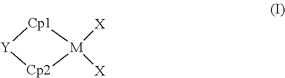

In the formula, M is an element selected from zirconium and hafnium.

Each of Cp1 and Cp2 is a cyclopentadienyl group having no substituent or a cyclopentadienyl group having one or two alkyl substituents (preferably having 1 to 3 carbon atoms) having no cyclic structure. Cp1 and Cp2 may be the same as or different from each other. One of the Cp1 and Cp2 groups may be an indenyl group having no substituent or an indenyl group having one or two alkyl substituents (preferably having 1 to 3 carbon atoms) having no cyclic structure.

Y has bonds to Cp1 and Cp2 and is a hydrogen atom or an element selected from carbon, silicon, germanium, and boron having substituents. The substituents (preferably alkyl groups or phenyl groups, etc.) may be the same as or different from each other and may have a cyclic structure (cyclohexyl structure, etc.).

Each X is independently selected from the group consisting of hydrogen, halogen, an alkyl group, and an aryl group, or two X moieties are bonded to constitute a diene group.

Further examples of such a compound (catalyst or co-catalyst) may also include those described in European Patent Application Publication No. 0872492A2, Japanese Patent Laid-Open No. 11-130808, Japanese Patent Laid-Open No. 9-309925, International Publication No. WO 00/20426, European Patent Application Publication No. 0985689, and Japanese Patent Laid-Open No. 6-184179.

In a preferable embodiment, the present composition can contain 1.0 ppm or more and 1000 ppm or less, more preferably 1.0 ppm or more and 100 ppm or less, of zirconium. Preferably, the mass ratio of zirconium to aluminum (Zr/Al ratio) contained in the present composition can be in the range of 0.013 or more and 0.5 or less, more preferably in the range of 0.013 or more and 0.1 or less. When the Zr/Al ratio falls within this range, an effect of improving dielectric characteristics and transparency tends to be easily obtained.

The component (A) contained in the present composition is preferably an olefin-aromatic vinyl compound-aromatic polyene copolymer (hereinafter, also simply referred to as a “copolymer”) that satisfies conditions given below. The component
(A) is a component that imparts curability to the present composition through a cross-linking bond.
(1) A number-average molecular weight of the copolymer is 5000 or larger and 40000 or smaller,
(2) an aromatic vinyl compound monomer unit is an aromatic vinyl compound having 8 or more and 20 or less carbon atoms, and a content of the aromatic vinyl compound monomer unit is 0% by mass or more and 70% by mass or less, preferably more than 0% by mass and 70% by mass or less,
(3) an aromatic polyene monomer unit is one or more selected from polyenes having 5 or more and 20 or less carbon atoms and having a plurality of vinyl groups and/or vinylene groups in a molecule, and
(4) an olefin monomer unit is one or more selected from olefins having 2 or more and 20 or less carbon atoms, and the total amount of the olefin monomer unit, the aromatic vinyl compound monomer unit, and the aromatic polyene monomer unit is 100% by mass.

The condition (3) further preferably satisfies the following condition (3a):
(3a) the aromatic polyene monomer unit is one or more selected from polyenes having 5 or more and 20 or less carbon atoms and having a plurality of vinyl groups and/or vinylene groups in a molecule, and a content of the vinyl groups and/or the vinylene groups derived from the aromatic polyene monomer unit is 1.5 or more and 20 or less per number-average molecular weight.

In the present specification, the average molecular weights (Mn and Mw) of the composition that satisfies the conditions of the amounts of the components (B) and (C) mentioned above (i.e., the components (B) and (C) are in very small amounts as compared with the component (A)) can be regarded as being substantially equal to those of the component (A) contained in this composition.

In the present specification, the olefin monomer unit is one or more selected from α-olefin having 2 or more and 20 or less carbon atoms and cyclic olefin having 5 or more and 20 or less carbon atoms, and refers to a compound (unit) that is substantially free of oxygen, nitrogen, and halogen and constituted by carbon and hydrogen. Examples of the α-olefin having 2 or more and 20 or less carbon atoms include, but are not particularly limited to, ethylene, propylene, 1-butene, 1-hexene, 1-octene, 1-decene, 1-dodecene, 4-methyl-1-pentene, and 3,5,5-trimethyl-1-hexene. Examples of the cyclic olefin having 5 or more and 20 or less carbon atoms include, but are not particularly limited to, norbornene and cyclopentene. The olefin monomer unit can be preferably a combination of ethylene and α-olefin other than ethylene or cyclic olefin. In a preferable embodiment, the olefin monomer unit can comprise one or more selected from the group consisting of ethylene and α-olefin having 3 or more carbon atoms.

In the present specification, the aromatic vinyl compound monomer unit refers to an aromatic vinyl compound (unit) having 8 or more and 20 or less carbon atoms. Examples of the aromatic vinyl compound monomer unit include, but are not particularly limited to, styrene, p-methylstyrene, p-isobutylstyrene, various vinylnaphthalenes, and various vinylanthracenes.

In the present specification, the aromatic polyene monomer unit refers to a polyene compound (unit) having 5 or more and 20 or less carbon atoms and having a plurality of vinyl groups and/or vinylene groups in a molecule thereof. Examples of the aromatic polyene monomer unit preferably include, but are not particularly limited to, compounds that have an aromatic vinyl structure such as each divinylbenzene in o-, m-, or p-form or a mixture thereof, divinylnaphthalene, divinylanthracene, p-2-propenylstyrene, or p-3-butenylstyrene, and are substantially free of oxygen, nitrogen, and halogen and constituted by carbon and hydrogen. As for the aromatic polyene monomer unit, a difunctional aromatic vinyl compound, for example, 1,2-bis(vinylphenyl) ethane (abbreviation: BVPE), described in Japanese Patent Laid-Open No. 2004-087639 may be used as the aromatic polyene monomer. Among them, preferably, each divinylbenzene in o-, m-, or p-form or a mixture thereof is used, and preferably, a mixture of m-divinylbenzene and p-divinylbenzene can be used. In the present specification, these divinylbenzenes are referred to as divinylbenzene(s). Divinylbenzene(s) is preferably used as the aromatic polyene because curing efficiency is high in curing treatment and curing is easy.

In the copolymer, the content of the vinyl groups and/or the vinylene groups (preferably the vinyl groups) derived from the aromatic polyene monomer unit can be 1.5 or more and 20 or less or 1.5 or more and less than 20, preferably 2 or more and less than 7, per number-average molecular weight. When the content of the vinyl groups and/or the vinylene groups is 1.5 or more, cross-linking efficiency is enhanced so that a cured product having a sufficient cross-linking density tends to be easily obtained. The content of the vinyl groups derived from the aromatic polyene unit (divinylbenzene unit) per number-average molecular weight in the copolymer can be obtained, for example, by comparing a standard polystyrene-based number-average molecular weight (Mn) determined by GPC (gel permeation chromatography) known to those skilled in the art with an aromatic polyene unit-derived vinyl group content obtained by ¹H-NMR measurement. As an example, when the content of the vinyl groups derived from the aromatic polyene unit (divinylbenzene unit) in the copolymer is 0.6% by mass by the intensity comparison of peak areas obtained by ¹H-NMR measurement and the standard polystyrene-based number-average molecular weight is 49000 by GPC measurement, the molecular weight of the vinyl groups derived from the aromatic polyene unit in this number-average molecular weight is 299 as the product thereof, which is divided by the formula weight 130 of the vinyl groups to obtain 2.3. In short, the content of the vinyl groups derived from the aromatic polyene unit per number-average molecular weight in this copolymer is determined as 2.3. The attributions of peaks obtained by the ¹H-NMR measurement of the copolymer are known by documents. A method for determining the composition of the copolymer from the comparison of peak areas obtained by ¹H-NMR measurement is also known. It is further possible to improve the accuracy of the composition by adding data on peak areas of 13C-NMR spectra measured in a known quantitative mode or ratios thereof to this method based on ¹H-NMR measurement. In the present specification, the content of the divinylbenzene unit in the copolymer is determined from the peak intensity (by ¹H-NMR measurement) of the vinyl groups derived from the divinylbenzene unit. Specifically, the content of the divinylbenzene unit is determined from the content of the vinyl groups derived from the divinylbenzene unit on the assumption that one vinyl group is derived from one divinylbenzene unit in the copolymer.

In the present specification, the number-average molecular weight (Mn) and the weight-average molecular weight (Mw) are calculated as standard polystyrene-based molecular weights obtained by GPC (gel permeation chromatography).

The number-average molecular weight (Mn) of the present composition is 40000 or smaller and can be preferably 5000 or larger and 40000 or smaller, more preferably 5000 or larger and 30000 or smaller, further preferably 5000 or larger and 20000 or smaller.

The present composition can have a weight-average molecular weight (Mw) of preferably 18000 or larger, further preferably Mw of 18000 or larger and 100000 or smaller, from the viewpoint of improvement in dielectric characteristics.

In a preferable embodiment, the value of the ratio Mw/Mn of the weight-average molecular weight (Mw) to the number-average molecular weight (Mn) of the present composition can be appropriately set depending on desired performance and is not particularly limited. The value can be preferably 10 or less, more preferably 1 or more and 10 or less, further preferably 2 or more and 10 or less. When Mw/Mn is 10 or less, a molecular weight distribution is optimized to produce an effect of obtaining proper dielectric characteristics.

In an embodiment of the present invention, the present composition may further comprise one or more of the following components:
(a) a curing agent,
(b) one or more resins selected from a hydrocarbon-based elastomer, a polyether-based resin, and an aromatic polyene-based resin,
(c) a monomer, and
(d) an olefin-aromatic vinyl compound-aromatic polyene copolymer different from the copolymer described above, the olefin-aromatic vinyl compound-aromatic polyene copolymer satisfying all of the following conditions (i) to (iv):
(i) a number-average molecular weight of the copolymer is 500 or larger and 100000 or smaller, preferably 500 or larger and smaller than 5000 or larger than 40000 and 100000 or smaller,
(ii) an aromatic vinyl compound monomer unit is an aromatic vinyl compound having 8 or more and 20 or less carbon atoms, and a content of the aromatic vinyl compound monomer unit is 70% by mass or less, preferably more than 0% by mass and 70% by mass or less,
(iii) an aromatic polyene monomer unit has a plurality of vinyl groups and/or vinylene groups in a molecule, and
(iv) an olefin monomer unit is one or more selected from olefins having 2 or more and 20 or less carbon atoms, a content of the olefin monomer unit is 30% by mass or more, and the total amount of the olefin monomer unit, the aromatic vinyl compound monomer unit, and the aromatic polyene monomer unit is 100% by mass.

The condition (iii) preferably satisfies the following condition (iiia):
(iiia) the aromatic polyene monomer unit is one or more selected from polyenes having 5 or more and 20 or less carbon atoms and having a plurality of vinyl groups and/or vinylene groups in a molecule, and a content of the vinyl groups and/or the vinylene groups derived from the aromatic polyene monomer unit is 1.5 or more and 20 or less per number-average molecular weight.

Such a different copolymer can be a copolymer described in, for example, International Publication Nos. WO 2021/112087, WO 2021/112088, and WO 2022/014599. Such a different olefin-aromatic vinyl compound-aromatic polyene copolymer that satisfies all the specific conditions mentioned above is soft and tends to exhibit a low permittivity and a low dielectric tangent and therefore, can be combined with the present compound of the component (A) mentioned above and prepared into a composition to offer a cured product that has a low permittivity and a low dielectric tangent and covers a wide range of physical properties.

### <Curing Agent>

A heretofore known curing agent that can be used in the polymerization or curing of an aromatic polyene and an aromatic vinyl compound may be used as the curing agent that may be contained in the present composition. Examples of such a curing agent include radical polymerization initiators (radical generators), cationic polymerization initiators, and anionic polymerization initiators. Preferably, a radical polymerization initiator can be used, and its type is not particularly limited. The curing agent is further preferably an organic peroxide-based or azo-based polymerization initiator, a dicumene initiator (e.g., 2,3-dimethyl-2,3-diphenylbutane), or the like, and can be freely selected depending on application and conditions. For example, a dicumene initiator requires a high temperature for reaction and is therefore unlikely to cause side reaction in cured product preparation and tends to be easily handled. A catalog in which organic peroxides are listed can be downloaded from the homepage of NOF Corp., for example, https://www.nof.co.jp/business/functional-materials/functional-materials-product09. Alternatively, an organic peroxide also described in, for example, the catalog of FUJIFILM Wako Pure Chemical Corp, or Tokyo Chemical Industry Co., Ltd. may be used. Also, a known photopolymerization initiator using light, ultraviolet ray, or radiation may be used as the curing agent. Examples of the photopolymerization initiator include radical photopolymerization initiators, cationic photopolymerization initiators, and anionic photopolymerization initiators. Such a photopolymerization initiator is available from, for example, Tokyo Chemical Industry Co., Ltd. Curing with radiation or electron beam itself may be performed. Cross-linking or curing may be performed by the thermal polymerization of a contained starting material without involving the curing agent.

The amount of the curing agent used is not particularly limited. For example, 0.01 to 10 parts by mass of the curing agent can be contained per 100 parts by mass of the present compound of the component (A). In the case of using a curing agent such as a peroxide-based or azo-based polymerization initiator or a dicumene initiator, curing treatment is performed using a proper temperature and time in consideration of its half-life. In this case, the conditions are arbitrary depending on the curing agent and generally involve a temperature range on the order of 50° C. to 200° C., and more preferably, a temperature range on the order of 50° C. to 300° C. is appropriate.

### <Hydrocarbon-Based Elastomer>

The amount of the hydrocarbon-based elastomer used, which may be contained in the present composition, can be appropriately set depending on desired performance and is not particularly limited. The amount is preferably 1 to 200 parts by mass, more preferably 1 to 100 parts by mass, most preferably 1 to 50 parts by mass, per 100 parts by mass of the present compound of the component (A). The hydrocarbon-based elastomer has a number-average molecular weight of preferably 100 or larger and 100000 or smaller, more preferably 1000 or larger and 4500 or smaller. Examples of the hydrocarbon-based elastomer can preferably include, but are not particularly limited to, one or more elastomers selected from ethylene-based and propylene-based elastomers, conjugated diene-based polymers, aromatic vinyl compound-conjugated diene-based block copolymers and random copolymers, and their hydrides (hydrogenated products). Examples of the ethylene-based elastomer include, but are not particularly limited to, ethylene-α olefin copolymers such as ethylene-octene copolymers and ethylene-1-hexene copolymers, EPR, and EPDM. Examples of the propylene-based elastomer include, but are not particularly limited to, atactic polypropylene, low tactic polypropylene, and propylene-α olefin copolymers such as propylene-1-butene copolymers.

Examples of the conjugated diene-based polymer include, but are not particularly limited to, polybutadiene and 1,2-polybutadiene. Examples of the aromatic vinyl compound-conjugated diene-based block copolymer or random copolymer and their hydrides (hydrogenated products) include, but are not particularly limited to, SBS, SIS, SEBS, SEPS, SEEPS, and SEEBS. The 1,2-polybutadiene that can be preferably used is available as liquid polybutadiene under product names of B-1000, 2000, and 3000 from Nippon Soda Co., Ltd. Examples of the copolymer having a 1,2-polybutadiene structure that can be preferably used include product name “Ricon100” from TOTAL CRAY VALLEY. Particularly, when one or more resins selected from these hydrocarbon-based elastomers are in a liquid state (roughly 300000 mPa·s or less) at room temperature (25° C.), the amount of the resins used can be in the range of preferably 150 parts by mass or less, more preferably 1 to 30 parts by mass, most preferably 1 to 20 parts by mass, per 100 parts by mass of the present compound of the component (A) from the viewpoint of the handleability or molding processability (handleability as a thermoplastic resin) in an uncured state of the present composition.

### <Polyether-Based Resin>

Examples of the polyether-based resin that may be used in the present composition include polyphenylene ether and polyether. Commercially available known polyphenylene ether can be used as the polyphenylene ether, and its type is not particularly limited. The number-average molecular weight of the polyphenylene ether is arbitrary, can be appropriately set depending on desired performance, and is not particularly limited. The number-average molecular weight (Mn) is preferably 10000 or smaller, most preferably 5000 or smaller, in consideration of the molding processability of the composition. The number-average molecular weight can be preferably 500 or larger.

For addition aimed at curing the present composition, the molecular ends of the polyether-based resin such as polyphenylene ether are preferably modified with a functional group. For addition aimed at curing the present composition, the polyether-based resin such as polyphenylene ether preferably has a plurality of functional groups in one molecule. The polyether-based resin can be, for example, modified polyphenylene ether. Examples of the functional group include radical polymerizable functional groups and functional groups such as an epoxy group. A radical polymerizable functional group is preferred. The radical polymerizable functional group is preferably a vinyl group. The vinyl group is preferably one or more selected from the group consisting of an allyl group, a (meth)acryloyl group, and an aromatic vinyl group, more preferably one or more selected from the group consisting of a (meth)acryloyl group and an aromatic vinyl group, most preferably an aromatic vinyl group. In short, in the composition of the present embodiment, difunctional polyphenylene ether in which both ends of a molecular chain are modified with a radical polymerizable functional group is particularly preferred. Examples of such polyphenylene ether include Noryl™ SA9000 from SABIC Japan LLC (modified polyphenylene ether having a methacryloyl group at both ends, number-average molecular weight: 2200), and a bifunctional polyphenylene ether oligomer manufactured by Mitsubishi Gas Chemical Co., Inc. (OPE-2St, modified polyphenylene ether having a vinylbenzyl group at both ends, number-average molecular weight: 1200). Alternatively, allylated PPE from Asahi Kasei Corp. may be used. Among them, a bifunctional polyphenylene ether oligomer manufactured by Mitsubishi Gas Chemical Co., Inc. (OPE-2St) can be preferably used.

For example, aromatic polyether from JSR Corp. (ELPAC HC-F series) may be used as the polyether-based resin. The amount of the polyether-based resin such as polyphenylene ether used in the present composition can be appropriately set depending on desired performance and is not particularly limited. The amount is preferably 1 to 200 parts by mass, more preferably 1 to 100 parts by mass, per 100 parts by mass of the component (A).

### <Aromatic Polyene-Based Resin>

The aromatic polyene-based resin that may be contained in the present composition encompasses a divinylbenzene-based reactive multibranched copolymer (PDV) manufactured by NIPPON STEEL Chemical & Material Co., Ltd. Such PDV is described in, for example, the document “Syntheses of Multi-Functional Aromatic Copolymers (PDVs) with Controlled Molecular Architectures and Development of Novel Low Dielectric Loss Materials from PDVs” (Masanao Kawabe, Journal of the Japan Institute of Electronics Packaging, p. 125, Vol. 12 No. 2 (2009)). The amount of the aromatic polyene-based resin used in the present composition can be appropriately set depending on desired performance and is not particularly limited. The amount is preferably 1 to 200 parts by mass, more preferably 1 to 100 parts by mass, most preferably 1 to 50 parts by mass, per 100 parts by mass of the present compound of the component (A). Use of the aromatic polyene-based resin within these preferred numerical ranges is preferred for preventing reduction in adhesiveness to other members or reduction in toughness.

### <Monomer>

The amount of the monomer used, which may be contained in the present composition, can be preferably 100 parts by mass or less per 100 parts by mass of the present compound of the component (A), or the present composition may substantially comprise no monomer. In the present specification, the monomer is a monomer polymerizable by any of radical polymerization, cationic polymerization, and anionic polymerization, and is preferably a radical polymerizable monomer. Its molecular weight is preferably 5000 or smaller, preferably smaller than 5000, more preferably 1000 or smaller, more preferably smaller than 1000, further preferably 500 or smaller, further preferably smaller than 500. The monomer may comprise a monomer having the same structure as that of the monomer unit of the “aromatic vinyl compound” or the “aromatic polyene” mentioned above. Preferably, the monomer may comprise the following polar monomer.

### <Polar Monomer>

The amount of the polar monomer used, which may be contained in the present composition, can be appropriately set depending on desired performance and is not particularly limited. The amount can be preferably 100 parts by mass or less, more preferably in the range of 0.1 to 20 parts by mass, further preferably 0.1 to 10 parts by mass, per 100 parts by mass of the present compound of the component (A). Use of the polar monomer within these preferred numerical ranges tends to produce an effect of allowing the resulting cured product to not have too high a permittivity or dielectric tangent. In the present specification, the polar monomer is a monomer having one or more atoms selected from oxygen, nitrogen, phosphorus, and sulfur in a molecule. The polar monomer that can be preferably used has a molecular weight of preferably smaller than 5000, more preferably smaller than 1000, further preferably smaller than 500. The polar monomer is preferably a polar monomer polymerizable using a radical polymerization initiator. Examples of the polar monomer include, but are not particularly limited to, various maleimides, bismaleimides, maleic anhydride, triallyl isocyanurate, glycidyl (meth)acrylate, tri(meth)acryl isocyanurate, and trimethylolpropane tri(meth)acrylate. The maleimides and the bismaleimides that may be used in the present embodiment are described in, for example, International Publication No. WO 2016/114287 and Japanese Patent Laid-Open No. 2008-291227 and can be purchased from, for example, Daiwa Kasei Industrial Co., Ltd., Nippon Kayaku Co., Ltd., or Designer Molecules Inc. Alternatively, a bismaleimide-based resin “SLK” manufactured by Shin-Etsu Chemical Co., Ltd. may be used. Such a maleimide group-containing compound is preferably bismaleimides from the viewpoint of solubility in an organic solvent, high-frequency characteristics, high adhesiveness to a conductor, the moldability of a prepreg, and the like. Such a maleimide group-containing compound may be used as a polyaminobismaleimide compound from the viewpoint of solubility in an organic solvent, high-frequency characteristics, high adhesiveness to a conductor, the moldability of a prepreg, and the like. The polyaminobismaleimide compound can be obtained, for example, through the Michael addition reaction of a compound having two terminal maleimide groups with an aromatic diamine compound having two primary amino groups in a molecule. In the case of attempting to obtain high cross-linking efficiency by addition in a small amount, a polar monomer having a difunctional or higher multifunctional group is preferably used. Examples of such a polar monomer include bismaleimides, triallyl isocyanurate (TAlC), and trimethylolpropane tri(meth)acrylate.

### <Different Olefin-Aromatic Vinyl Compound-Aromatic Polyene Copolymer>

The present composition may comprise one or more selected from olefin-aromatic vinyl compound-aromatic polyene copolymers different from the copolymer mentioned above, and this different copolymer can satisfy any of the following conditions:
(i) a number-average molecular weight of the copolymer is 500 or larger and 100000 or smaller, preferably 500 or larger and smaller than 5000 or larger than 40000 and 100000 or smaller,
(ii) an aromatic vinyl compound monomer unit is an aromatic vinyl compound having 8 or more and 20 or less carbon atoms, and a content of the aromatic vinyl compound monomer unit is 70% by mass or less, preferably more than 0% by mass and 70% by mass or less,
(iii) an aromatic polyene monomer unit is one or more selected from polyenes having 5 or more and 20 or less carbon atoms and having a plurality of vinyl groups and/or vinylene groups in a molecule, and a content of the vinyl groups and/or the vinylene groups derived from the aromatic polyene unit is 1.5 or more and 20 or less per number-average molecular weight, and
(iv) an olefin monomer unit is one or more selected from olefins having 2 or more and 20 or less carbon atoms, a content of the olefin monomer unit is 30% by mass or more, and the total amount of the olefin monomer unit, the aromatic vinyl compound monomer unit, and the aromatic polyene monomer unit is 100% by mass.

### <Production Method>

The present composition can be produced by the application of a known production process, and a method for producing the present composition is not particularly limited. The present composition may be produced on the basis of a method described in, for example, Japanese Patent Laid-Open No. 2009-161743, Japanese Patent Laid-Open No. 2010-280771, or International Publication No. WO 00/37517. A single-site coordination polymerization catalyst constituted by a transition metal compound and a co-catalyst is preferably used because an olefin-aromatic vinyl compound-aromatic polyene copolymer can be efficiently produced. In the production method, a transition metal compound represented by the general formula (I) mentioned above can be added as a catalyst to a starting material comprising an olefin monomer, an aromatic vinyl compound monomer, and an aromatic polyene monomer.

The composition may be produced by further adding a co-catalyst comprising one or more selected from the group consisting of an organic aluminum compound and a boron compound to form an active species composed of the catalyst and the co-catalyst, and initiating single-site coordination polymerization reaction of the starting material.

### <Varnish>

An embodiment according to the present invention can provide a varnish comprising the composition mentioned above and a solvent. In the present specification, a liquid form obtained by comprising a solvent is particularly referred to as a varnish.

The varnish has proper viscosity as mentioned above and exhibits a viscous liquid state. The varnish is applied to another material by an appropriate method of coating, impregnation, filling, or dropwise addition, and the solvent can be removed to prepare a molded product. A cured product of interest can be obtained by further curing with heat or light. Such properties are useful because a sheet or a film can be formed by various techniques of transfer molding, application onto or to between substrate(s) or semiconductor device material(s), extrusion lamination, or spin coating and then cured to form an insulation coating or an insulation layer. A polymerization solution (generally containing the present compound which is the copolymer as well as a solvent for use in polymerization such as toluene, ethylbenzene, cyclohexane, or methylcyclohexane, a residual monomer of styrene, divinylbenzene, or the like, a residual monomer of an olefin monomer or the like, a catalyst, and a co-catalyst component) for use in the production of the present compound which is the copolymer may be used in itself as the varnish. Alternatively, the varnish can also be obtained by distilling off a portion or the whole of the solvent and the residual monomers under reduced pressure from this polymerization solution, and, if necessary, diluting the residue with the solvent. In short, the present varnish may comprise a residual monomer from polymerization or a solvent used in polymerization.

### <Solvent>

The present composition may be supplemented, if necessary, with a proper solvent. The amount of the solvent used is not particularly limited. The solvent is used for adjusting the viscosity or fluidity of the composition. Particularly, when the resin composition of the present embodiment is in a varnish state, the solvent is preferably used. When the solvent has a high boiling point, i.e., is low volatile, under atmospheric pressure, the resulting coating film has a uniform thickness. Therefore, the solvent preferably has a boiling point above a certain level. The boiling point is preferably roughly 75° C. or higher, more preferably 100° C. or higher and 300° C. or lower, further preferably 130° C. or higher and 300° C. or lower, under atmospheric pressure. A solvent known in the art can be used, and the solvent is not particularly limited. For example, cyclohexane, cyclohexanone, methyl ethyl ketone (MEK), toluene, ethylbenzene, xylene, mesitylene, tetralin, acetone, limonene, mixed alkane, or a mixed aromatic solvent is used. The amount of the solvent used in the composition of the present embodiment can be appropriately set depending on desired performance. The amount is arbitrary and is preferably 5 to 500 parts by mass, more preferably 10 to 300 parts by mass, most preferably 50 to 150 parts by mass, per 100 parts by mass of the present compound which is the copolymer.

When a starting material low soluble in toluene or other aromatic solvents, for example, specific bismaleimide, is used as a constituent of the present composition, methyl ethyl ketone (MEK) can be used as the solvent.

The present composition or the varnish may contain an additive that is usually used in a resin in the art, for example, an antioxidant, a weathering agent, a light stabilizer, a lubricant, a compatibilizing agent, and an antistatic agent, without inhibiting a desired effect or the object. The composition or the varnish of the present embodiment is obtained by mixing and dissolving or melting various additives described above, and an arbitrary known method can be adopted to a mixing, dissolution, or melting method.

The present composition can be mixed using a known kneading method, for example, a twin-shaft kneading machine, various rolls, or various kneaders. When the composition is the varnish, the composition may be mixed by addition to the varnish and stirring.

An embodiment according to the present invention can also provide a cured product of the composition or the varnish mentioned above. The cured product can be used in the production of a CCL substrate, an FCCL substrate, an interlayer insulation material, or a coverlay. Specifically, the present composition is particularly preferred as an electronic insulation material for high-frequency signals.

### <Molded Product>

A molded product obtained from the present composition or the like has an arbitrary shape. Such a composition can exhibit the properties of a thermoplastic resin. Hence, the composition can be molded into a shape such as a sheet, a tube, a strip, or pellets in a substantially uncured state by a molding processing method known for thermoplastic resins, for example, extrusion molding, injection molding, press molding, or inflation molding, under conditions that do not cause cross-linking and can then be cross-linked (cured). When the composition is, for example, the varnish, a molded product in a sheet or film form can generally be prepared by coating a base material with the varnish and then removing the solvent by heating, pressure reduction, air drying, or the like. An uncured sheet or film can be obtained by these methods. Also, a composite may be obtained by impregnating a porous base material, a woven fabric, or a nonwoven fabric with the present varnish and removing the solvent. For example, a hemispherical shape may be formed by adding the varnish dropwise onto a base material and removing the solvent. The sheet may be uncured (semicured) to the extent that the sheet shape can be maintained, or may be a product after complete curing. The degree of curing of the composition can be quantitatively measured by known dynamic mechanical analysis (DMA).

### <Curing>

The molded product obtained from the present composition or the like can be cured by a known method with reference to curing conditions (temperature, time, and pressure) for the starting material or the curing agent contained therein. When the curing agent used is a peroxide, the curing conditions can be determined with reference to a half-life temperature and the like disclosed on a peroxide basis.

The cured product of the molded product obtained from the present composition or the like is in a sufficiently cured state, and its gel content (gel fraction) measured in accordance with ASTM is not particularly limited and can be 90% by mass or more. The dielectric tangent of the cured product at a measurement frequency of 40 GHz and 23° C. is not particularly limited and is preferably 0.003 or less, more preferably 0.002 or less, further preferably 0.001 or less.

An embodiment of the present invention may provide a CCL substrate, an FCCL substrate, an interlayer insulation material, a coverlay, and the like comprising the cured product.

### EXAMPLES

Hereinafter, features of the present invention will be described further specifically with reference to Examples and Comparative Examples. However, the present invention is not limited by these examples by any means. Specifically, materials, amounts of use, proportions, treatment contents, treatment procedures, and the like shown in Examples given below can be appropriately changed or modified without departing from the spirit of the present invention. Values of various production conditions and evaluation results in Examples given below mean a preferable upper limit value or a preferable lower limit value for embodiments of the present invention, and a preferable numerical range can be a range defined by a combination of the upper limit value or the lower limit value and a value described in each Example or values described in Examples.

### Examples 1 to 6 and Comparative Examples 1 to 3

Examples 1 to 6 and Comparative Examples 1 to 3 were prepared on the basis of the starting material formulations (indicated by mol % or ppm in the table) described in the table below. Each copolymer was produced on the basis of the production method described in Japanese Patent Laid-Open No. 2009-161743 or 2010-280771.

The following catalysts were used. The catalysts were indicated by the following symbols in the table.
Catalyst A: dimethylmethylene biscyclopentadienyl zirconium dichloride (Zr catalyst)
Catalyst B: diphenylmethylene (1-indenyl)cyclopentadienyl zirconium dichloride

The co-catalysts used were tritium tetrakis(pentafluorophenyl) borate (“TRI-FABA” manufactured by Tosoh Finechem Corp.), N,N-dimethylanilinium tetrakis(pentafluorophenyl) borate (“DAN-FABA” manufactured by Tosoh Finechem Corp.), and modified methylaluminoxane (“MMAO” manufactured by Tosoh Finechem Corp.). The co-catalysts were indicated by product names in the table.

The scavenger used was triisobutylaluminum (“TIBAL” manufactured by Tosoh Finechem Corp.). The amount of the scavenger added was adjusted by back calculation from the target amount of aluminum.

The solvent used was toluene. The starting material monomers used were ethylene (Et), styrene (St), divinylbenzene (DVB), and 1-hexene for some examples. Using a 10 L polymerization vessel with a stirrer and a jacket for heating and cooling, the catalyst and the co-catalyst were added to the starting material monomers, which were then polymerized for 2 hours at the polymerization temperature shown in the table, and isopropanol was added thereto to obtain an LDM resin solution. While stirred, the solution was concentrated by heating at 80° C. for 2 hours in a reduced-pressure state to obtain a composition of each of Examples and Comparative Examples.

TABLE 1

| | | | Example 1 | Example 2 | Example 3 | Example 4 | Example 5 |
|---|---|---|---|---|---|---|---|
| Catalyst | | | Catalyst | Catalyst | Catalyst | Catalyst | Catalyst |
| | | | A | A | B | B | A |
| Co-catalyst | | | TRI- | TRI- | TRI- | TRI- | DAN- |
| | | | FABA | FABA | FABA | FABA | FABA |
| Polymerization temperature | | ° C. | 80 | 50 | 60 | 60 | 60 |
| Et | | mol % | 80.0 | 80.1 | 68.1 | 79.3 | 80.2 |
| 1-Hexene | | mol % | 0.0 | 0.0 | 4.6 | 0.0 | 0.0 |
| St | | mol % | 18.5 | 17.8 | 22.5 | 20.1 | 17.8 |
| DVB | | mol % | 1.5 | 2.2 | 4.8 | 0.6 | 2.0 |
| Zr content | | ppm | 5.5 | 18.9 | 8.8 | 7.2 | 1.8 |
| Al content | | ppm | 312 | 822 | 241 | 546 | 126 |
| Zr/Al ratio | | | 0.018 | 0.023 | 0.037 | 0.013 | 0.015 |
| Boron content | | ppm | 0.7 | 2.4 | 1.3 | 1.0 | 0.2 |
| Mn | | | 5215 | 7132 | 9345 | 14571 | 7923 |
| Mw | | | 28797 | 25435 | 89563 | 49741 | 43101 |
| Mw/Mn | | | 5.5 | 3.6 | 9.6 | 3.4 | 5.4 |
| Dielectric | Permittivity | | 2.46 | 2.35 | 2.32 | 2.39 | 2.37 |
| characteristics | Dielectric | | 0.00077 | 0.00069 | 0.00056 | 0.00069 | 0.00074 |
| | tangent | | | | | | |
| Storage | Storage | Pa | 1.82E+09 | 1.16E+07 | 5.76E+07 | 2.98E+06 | 2.98E+06 |
| modulus | modulus at | | | | | | |
| (DMA) | 25° C. | | | | | | |

| | | | | | |
|---|---|---|---|---|---|
| Transparency (60 mass % | Good | Good | Good | Good | Good |
| solution) | | | | | |

| | | | | Comparative | Comparative | Comparative |
|---|---|---|---|---|---|---|
| | | | Example 6 | Example 1 | Example 2 | Example 3 |
| Catalyst | | | Catalyst | Catalyst | Catalyst | Catalyst |
| | | | A | A | A | B |
| Co-catalyst | | | TRI- | MMAO | MMAO | MMAO |
| | | | FABA | | | |
| Polymerization temperature | | ° C. | 60 | 60 | 80 | 60 |
| Et | | mol % | 72.7 | 79.3 | 80.5 | 75.1 |
| 1-Hexene | | mol % | 0.0 | 0.0 | 0.0 | 0.0 |
| St | | mol % | 24.5 | 18.7 | 17.7 | 24.2 |
| DVB | | mol % | 2.8 | 2.0 | 1.9 | 0.7 |
| Zr content | | ppm | 70.6 | 27.6 | 30.6 | 15.1 |
| Al content | | ppm | 1065 | 2196 | 2416 | 1527 |
| Zr/Al ratio | | | 0.066 | 0.013 | 0.013 | 0.010 |
| Boron content | | ppm | 9.0 | 0.0 | 0.0 | 0.0 |
| Mn | | | 7005 | 5696 | 4889 | 18412 |
| Mw | | | 18614 | 33058 | 34379 | 74593 |
| Mw/Mn | | | 2.7 | 5.8 | 7.0 | 4.1 |
| Dielectric | Permittivity | | 2.49 | 2.40 | 2.41 | 2.43 |
| characteristics | Dielectric | | 0.00085 | 0.00097 | 0.00090 | 0.00066 |
| | tangent | | | | | |
| Storage | Storage | Pa | 2.77E+07 | 4.07E+06 | 2.67E+06 | 3.46E+06 |
| modulus | modulus at | | | | | |
| (DMA) | 25° C. | | | | | |

| | | | | |
|---|---|---|---|---|
| Transparency (60 mass % | Good | NG | NG | NG |
| solution) | | | | |

The present compound which was the copolymer and the present composition thus obtained were analyzed by the following approaches.

### <Analysis of Chemical Structure of Compound>

The compositional ratio of each component is described in the table.

The compositional ratios of ethylene (Et), α-olefin (1-hexene in the present Examples), styrene (St), and divinylbenzene (DVB) in the copolymer, the content of a vinyl group unit derived from divinylbenzene, and the ratio between a terminal vinyl group and a terminal vinylidene group were calculated from peak area intensity attributed to each factor by ¹H-NMR (using the method mentioned above). A sample was dissolved in deuterated 1,1,2,2-tetrachloroethane, and measurement was performed at 23° C.

NMR spectral peaks were as follows.
0.7 to 1.02 ppm: α-olefin CH3, 3H
0.5 to 2.1 ppm: St+DVB+Et+α-olefin CH2, 2H
4.5 to 4.7 ppm: terminal vinylidene CH2, 2H . . . Vd
4.8 to 5.0 ppm: terminal vinyl CH2, 2H . . . Vn (2)
5.12 to 5.35, 5.6 to 5.8 ppm: DVB vinyl CH2, 2H . . . 2Vn
6.6 to 6.8 ppm: DVB vinyl CH, 1H
6.8 to 7.4 ppm: St aromatic ring C6H5, 5H, DVB aromatic ring C6H4, 4h

### <Measurement of Amounts of Component (B) and Component (C)>

The amounts were measured by ICP-emission spectroscopy under the following conditions in accordance with JIS K0116:2014.

0.5 g of the composition was weighed into a platinum crucible and ashed using a hot plate, an electrical cooking stove, and an electrical furnace (heated to 600° C. with the temperature gradually increased). 0.5 ml of HCl (1+1) (mixed solution of hydrochloric acid and water at a volume ratio of 1:1) and ultrapure water were added to the residue, which was then dissolved by warming and then brought to 5 ml to prepare a test solution. The test solution was quantitatively analyzed by ICP-emission spectroscopy (using 5110VDV manufactured by Agilent Technologies, Inc.).

### <Measurement of Molecular Weight>

The molecular weights of the copolymer were determined as a standard polystyrene-based number-average molecular weight (Mn) and weight-average molecular weight (Mw) by use of GPC (gel permeation chromatography), and their ratio (Mw/Mn) was also determined. Measurement was performed under the following conditions.
Column: two columns of TSK-GEL MultiporeHXL-M $7.8×300 mm (manufactured by Tosoh Corp.) were connected in series and used.
Column temperature: 40° C.
Solvent: THF (tetrahydrofuran)
Liquid sending flow rate: 1.0 ml/min
Detector: RI detector

### <Transparency of Solution>

Each composition was dissolved in toluene to prepare a solution containing 60% by mass of the composition. White paper with an X-mark written thereon with black oil-based ink was put under a 30 mL glass beaker conformable to JIS R3503:1994, and 30 mL of the prepared solution was poured into the beaker. A sample that allowed the X-mark to be seen with the naked eye from above the beaker was assessed as having “Good” transparency, and a sample that did not allow the X-mark to be seen with the naked eye from above the beaker was assessed as “NG”.

Each composition was cured by procedures described below, and physical properties of the cured product were measured as described below. Using a container with a heating and cooling jacket and a stirring blade, the composition produced as described above and a solvent (toluene) were heated to approximately 60° C. and stirred to dissolve the compound. Further, 1 part by mass of 2,5-dimethyl-2,5-bis(tert-butylperoxy) hexyne-3 (PERHEXYNE 25B manufactured by NOF Corp.) was added as a curing agent per 100 parts by mass of the composition, and the mixture was dissolved, stirred, and mixed to obtain a composition in a varnish state. The obtained composition was poured into a silicone mold (mold portion length: 7 cm, width: 7 cm, thickness: 0.2 mm) on a Teflon® sheet placed on a glass plate, dried in air, and then further dried at 60° C. for 3 hours or longer in a vacuum dryer to obtain an uncured sheet. The Teflon sheet and the SUS mold were placed under a load of 5 MPa in a press, and heat treatment was performed at 120° C. for 30 minutes, at 150° C. for 30 minutes, and then at 200° C. for 120 minutes, followed by the removal of the Teflon sheet and the SUS mold to obtain a cured sheet.

### <Permittivity and Dielectric Loss (Dielectric Tangent)>

The dielectric tangent was measured as a value at 23° C. and 40 GHz using a cavity resonator perturbation method (network analyzer 8722ES model manufactured by Agilent Technologies, Inc., split cylinder resonator manufactured by Keysight Technologies K.K., 40 GHZ) and using a 0.2 mm×25 mm×30 mm sample cut out of the sheet.

### <Storage Modulus>

Measurement was performed at a frequency of 1 Hz in a temperature range from 20° C. to +300° C. using a dynamic mechanical analysis (DMA) apparatus (Rheometrics RSA-III). A sample for measurement (3 mm×40 mm) was cut out of a film having a thickness of approximately 0.2 mm and measured to determine a storage modulus at 25° C. Major measurement parameters related to this measurement were as follows.
Measurement frequency: 1 Hz
Temperature increase rate: 3° C./min
Sample measurement length: 13 mm
Test Type=Dynamic Temperature Ramp (DTempRamp)
Initial Static Force: 5.0 g
Auto Tension Sensitivity: 1.0 g
Max Auto Tension Rate: 0.033 mm/s
Max Applied Strain: 1.5%
Min Allowed Force: 1.0 g
Strain: 0.1%

All the compositions according to Examples 1 to 6 were excellent in all of the dielectric characteristics, the storage modulus, and the transparency of a solution.

On the other hand, Comparative Examples 1 to 3 containing no component (B) were inferior in transparency of a solution.

1. A composition comprising:
(A) an olefin-aromatic vinyl compound-aromatic polyene copolymer,
(B) boron at a content of 0.2 ppm or more as measured by ICP-emission spectroscopy in accordance with JIS K0116:2014, and
(C) aluminum at a content in the range of 100 ppm or more and 2000 ppm or less as measured by ICP-emission spectroscopy in accordance with JIS K0116:2014,
the composition having a number-average molecular weight of 40000 or smaller.

2. The composition according to claim 1, wherein the component (A) satisfies the following conditions (1) to (4):
(1) a number-average molecular weight of the copolymer is 5000 or larger and 40000 or smaller,
(2) an aromatic vinyl compound monomer unit is an aromatic vinyl compound having 8 or more and 20 or less carbon atoms, and a content of the aromatic vinyl compound monomer unit is 0% by mass or more and 70% by mass or less,
(3) an aromatic polyene monomer unit is one or more selected from polyenes having 5 or more and 20 or less carbon atoms and having a plurality of vinyl groups and/or vinylene groups in a molecule, and
(4) an olefin monomer unit is one or more selected from olefins having 2 or more and 20 or less carbon atoms, and a total amount of the olefin monomer unit, the aromatic vinyl compound monomer unit, and the aromatic polyene monomer unit is 100% by mass.

3. The composition according to claim 2, wherein the condition (3) satisfies the following condition (3a):
(3a) the aromatic polyene monomer unit is one or more selected from polyenes having 5 or more and 20 or less carbon atoms and having a plurality of vinyl groups and/or vinylene groups in a molecule, and a content of the vinyl groups and/or the vinylene groups derived from the aromatic polyene monomer unit is 1.5 or more and 20 or less per number-average molecular weight.

4. The composition according to claim 1, wherein the content of the component (B) as measured by ICP-emission spectroscopy in accordance with JIS K0116:2014 is in the range of 0.2 ppm or more and 10 ppm or less.

5. The composition according to claim 1, wherein the content of the component (C) is in the range of 100 ppm or more and 1500 ppm or less.

6. The composition according to claim 5, wherein the content of the component (C) is in the range of 100 ppm or more and 1100 ppm or less.

7. The composition according to claim 1, wherein a value of a ratio Mw/Mn of a weight-average molecular weight (Mw) to the number-average molecular weight (Mn) is 10 or less.

8. A cured product of the composition according to claim 1.

9. A CCL substrate, an FCCL substrate, an interlayer insulation material, or a coverlay comprising the cured product according to claim 8.

10. A cured product of the composition according to claim 2.

11. A cured product of the composition according to claim 3.

12. A cured product of the composition according to claim 4.

13. A cured product of the composition according to claim 5.

14. A cured product of the composition according to claim 6.

15. A cured product of the composition according to claim 7.
